(19) United States
(12) Patent Application Publication
(10) Pub. No.: US 2017/0118849 A1
(43) Pub. Date: Apr. 27, 2017

(54) DISPLAY DEVICE AND METHOD FOR FABRICATING THE SAME

(71) Applicant: SAMSUNG DISPLAY CO., LTD., Yongin-si (KR)

(72) Inventors: Tae-eun Kim, Seoul (KR); Younhwan Jung, Hwaseong-si (KR)

(21) Appl. No.: 15/172,056

(22) Filed: Jun. 2, 2016

(30) Foreign Application Priority Data
Oct. 21, 2015 (KR) 10-2015-0146916

(51) Int. Cl. H05K 5/00; H05K 5/03; H05K 5/02

(52) U.S. Cl. CPC H05K 5/0017; H05K 5/0217; H05K 5/03; H05K 5/0008

(57) ABSTRACT

Provided is a display device. The display device includes a display module, which includes a flat display area and a first side display area that is bent from a first side of the flat display area, a frame under the display module, and includes a flat surface support portion that is overlapped with the flat display area, a first side surface support portion that is overlapped with the first side display area, and a coupling portion, and a bracket under the frame being detachably coupled to the frame through the coupling portion.

### CROSS-REFERENCE TO RELATED APPLICATION

This application claims priority to, and the benefit of, Korean Patent Application No. 10-2015-0146916, filed on Oct. 21, 2015, the content of which, in its entirety, is herein incorporated by reference.

### BACKGROUND

1. Field

The present disclosure relates to a display device from which a display module and a bracket are detachable, and a method for fabricating the same.

2. Description of the Related Art

Electronic equipment for providing an image to a user, such as smartphones, digital cameras, laptop computers, navigations, and smart televisions, includes an image display device for displaying an image. The image display device includes a display module that generates an image to display the image, and a bracket under the display module to protect the display module.

In recent years, various display devices are being developed. Such a display device may display an image in various directions in one apparatus. For example, a portion of a display area of a display screen may be bent in a specific direction. A process of assembling the display module applied to the display device with the bracket is different from that of assembling a display module of a flat panel display device with a bracket.

### SUMMARY

The present disclosure provides a display device to which a display module and a bracket are attached/detached.

The present disclosure also provides a method for fabricating a display device to which a display module and a bracket are attached/detached.

An embodiment of the inventive concept provides a display device including a display module, which includes a flat display area and a first side display area that is bent from a first side of the flat display area, a frame under the display module, and including a flat surface support portion that is overlapped with the flat display area, a first side surface support portion that is overlapped with the first side display area, and a coupling portion, and a bracket under the frame, and being detachably coupled to the frame through the coupling portion.

The flat surface support portion may define an opening.

The frame may include stainless steel.

The first side display area of the display module may include a curved portion corresponding to a quadrant on a cross section that is orthogonal to the first side.

The display device may further include an adhesion member configured to couple the display module to the frame.

The coupling portion of the frame may include a plurality of first female screws, the bracket may define a plurality of first through holes at an area overlapping the plurality of first female screws, and the display device may further include a plurality of first male screws configured to be coupled to the plurality of first female screws through the plurality of first through holes.

The display device may further include a cover under the bracket.

The coupling portion of the frame further may include a plurality of second female screws, the bracket may further define a plurality of second through holes at an area overlapping the plurality of second female screws, the cover may define a plurality of third through holes at an area overlapping the plurality of second through holes, and the display device may further include a plurality of second male screws configured to be coupled to the plurality of second female screws through the plurality of second and third through holes.

The coupling portion of the frame may include a plurality of first hooks, and the bracket may define a plurality of first through holes for receiving the plurality of first hooks.

The display device may further include a cover under the bracket.

The coupling portion of the frame may include a plurality of second hooks, the bracket may further include a plurality of second through holes for receiving the plurality of second hooks, and the cover may include third through holes for receiving the second hooks.

The display module may further include a second side display area that is bent from a second side of the flat display area that is opposite the first side of the flat display area.

The frame may further include a second side surface support portion overlapping the second side display area.

The first side display area and the second side display area may have the same radius of curvature, and the first side surface support portion and the second side surface support portions may have the same radius of curvature.

In an embodiment of the inventive concept, a method for fabricating a display device includes performing an alignment process in which a display module, which includes a flat display area, a first side display area bent from a first side of the flat display area, and a second side display area bent from a second side of the flat display area that is opposite the first side, is aligned with a frame, which includes a flat surface support portion, a first side surface support portion, a second side surface support portion, and a coupling portion, and is also aligned with a bracket, performing a pre-bending process in which at least one of the flat display area and the flat surface support portion is bent, performing an attachment process in which the flat display area and the flat surface support portion are attached to each other, the first side display area and the first side surface support portion are attached to each other, and the second side display area and the second side surface support portion are attached to each other, and performing an assembly process in which the frame is coupled to the bracket by using the coupling portion so that the frame is detachable from the bracket.

The display module may include a curved portion corresponding to a quadrant on a cross-section that is orthogonal to the first side.

The coupling portion of the frame may define a plurality of female screws, the bracket may define a plurality of through holes, and a plurality of male screws may be coupled to the plurality of female screws through the plurality of through holes during the assembly process.

The coupling portion of the frame may include a plurality of hooks, and the bracket may define a plurality of through holes into which the plurality of hooks is inserted during the assembly process.

The at least one of the flat display area and the flat surface support portion that is bent may return to its original shape during the performing the attachment process.

### BRIEF DESCRIPTION OF THE DRAWINGS

The accompanying drawings are included to provide further understanding of the inventive concept, and are incorporated in, and constitute a part of, this specification. The drawings illustrate exemplary embodiments of the inventive concept and, together with the description, serve to explain principles of the inventive concept. In the drawings:

FIG. 1 is a perspective view of a display device according to an embodiment of the inventive concept;

FIG. 2 is an exploded perspective view of the display device of FIG. 1;

FIG. 3 is an exploded cross-sectional view of the display device, taken along the line I-I′ of FIG. 1;

FIG. 4 is an exploded cross-sectional view of the display device, taken along the line II-II′ of FIG. 1;

FIG. 5 is a perspective view of a display device according to another embodiment of the inventive concept;

FIG. 6 is an exploded perspective view of the display device of FIG. 5;

FIG. 7 is an exploded cross-sectional view of the display device, taken along the line I-I′ of FIG. 5;

FIG. 8 is an exploded cross-sectional view of the display device, taken along the line II-II′ of FIG. 5;

FIG. 9 is a perspective view of a display device according to another embodiment of the inventive concept;

FIG. 10 is an exploded perspective view of the display device of FIG. 9;

FIG. 11 is an exploded cross-sectional view of the display device, taken along the line I-I′ of FIG. 9;

FIG. 12 is an exploded cross-sectional view of the display device, taken along the line II-II′ of FIG. 9;

FIG. 13 is a perspective view of a display device according to another embodiment of the inventive concept;

FIG. 14 is an exploded perspective view of the display device of FIG. 13;

FIG. 15 is an exploded cross-sectional view of the display device, taken along the line I-I′ of FIG. 13;

FIG. 16 is an exploded cross-sectional view of the display device, taken along the line II-II′ of FIG. 13;

FIGS. 17A, 17B, 17C, 17D, and 17E are cross-sectional views illustrating a method for fabricating a display device according to an embodiment of the inventive concept;

FIG. 18 is a flowchart of the method for fabricating the display device of FIGS. 17A, 17B, 17C, 17D, and 17E;

FIGS. 19A, 19B, 19C, 19D, and 19E are cross-sectional views illustrating a method for fabricating a display device according to an embodiment of the inventive concept; and

FIG. 20 is a flowchart of the method for fabricating the display device of FIGS. 19A, 19B, 19C, 19D, and 19E.

### DETAILED DESCRIPTION

Features of the inventive concept and methods of accomplishing the same may be understood more readily by reference to the following detailed description of embodiments and the accompanying drawings. Hereinafter, example embodiments will be described in more detail with reference to the accompanying drawings, in which like reference numbers refer to like elements throughout. The present invention, however, may be embodied in various different forms, and should not be construed as being limited to only the illustrated embodiments herein. Rather, these embodiments are provided as examples so that this disclosure will be thorough and complete, and will fully convey the aspects and features of the present invention to those skilled in the art. Accordingly, processes, elements, and techniques that are not necessary to those having ordinary skill in the art for a complete understanding of the aspects and features of the present invention may not be described. Unless otherwise noted, like reference numerals denote like elements throughout the attached drawings and the written description, and thus, descriptions thereof will not be repeated. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element, layer, region, or component is referred to as being “on,” “connected to,” or “coupled to” another element, layer, region, or component, it can be directly on, connected to, or coupled to the other element, layer, region, or component, or one or more intervening elements, layers, regions, or components may be present. In addition, it will also be understood that when an element or layer is referred to as being “between” two elements or layers, it can be the only element or layer between the two elements or layers, or one or more intervening elements or layers may also be present.

In the following examples, the x-axis, the y-axis and the z-axis are not limited to three axes of a rectangular coordinate system, and may be interpreted in a broader sense. For example, the x-axis, the y-axis, and the z-axis may be perpendicular to one another, or may represent different directions that are not perpendicular to one another.

The terminology used herein is for the purpose of describing particular embodiments only and is not intended to be limiting of the present invention. As used herein, the singular forms “a,” “an,” and “the” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

When a certain embodiment may be implemented differently, a specific process order may be performed differently from the described order. For example, two consecutively described processes may be performed substantially at the same time or performed in an order opposite to the described order.

The electronic or electric devices and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the exemplary embodiments of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

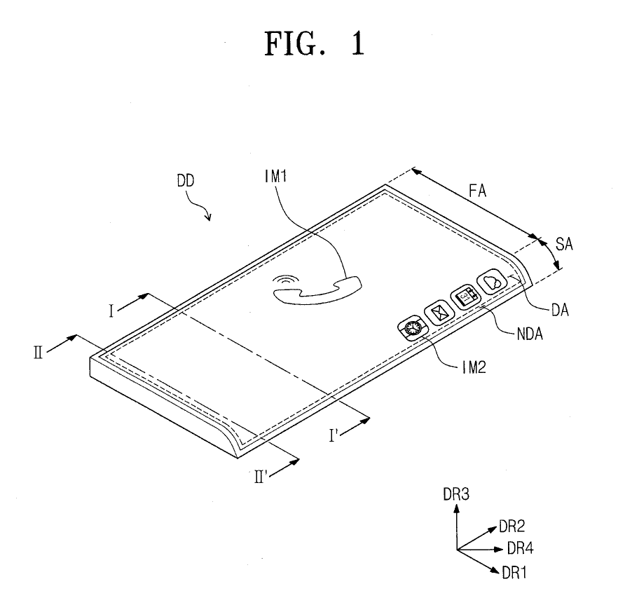

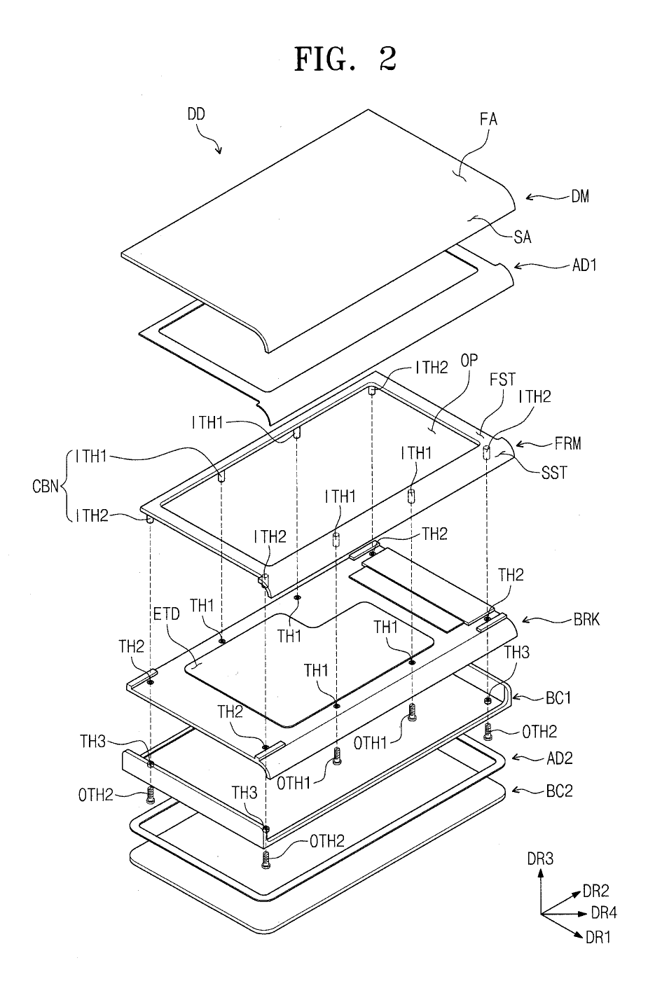

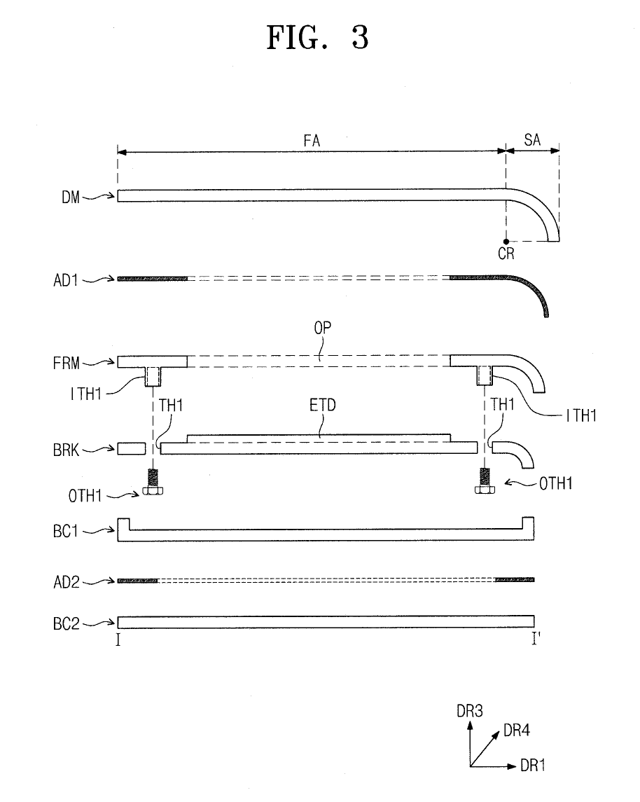

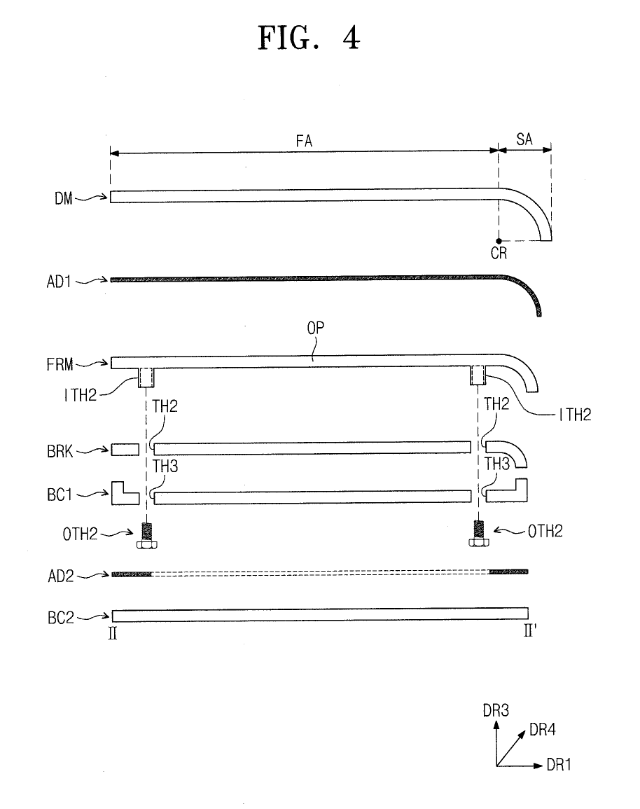

FIG. 1 is a perspective view of a display device DD according to an embodiment of the inventive concept, FIG. 2 is an exploded perspective view of the display device DD of FIG. 1, FIG. 3 is an exploded cross-sectional view of the display device DD, taken along the line I-I′ of FIG. 1, and FIG. 4 is an exploded cross-sectional view of the display device DD, taken along the line II-II′ of FIG. 1.

FIG. 1 is illustrates the display device DD that is applicable to smart phones according to an embodiment of the inventive concept. However, the inventive concept is not limited thereto. For example, the display device DD may be applied to electronic devices, such as televisions, personal computers, laptop computers, navigation units for vehicles, game consoles, acoustic electronic devices, smart watches, and cameras. The above-described devices are only exemplified as an embodiment, and thus, the display device DD may be adopted for other electronic devices.

As illustrated in FIG. 1, the display device DD includes a display area DD (or a display portion) on which an image is displayed, and a non-display area NDA (or a non-display portion) on which an image is not displayed. In the current embodiment, the terms the “display area DA” and the “non-display area NDA” may define the display device DD through a plurality of areas (or portions) that are divided according to whether an image may be displayed or not. Although the non-display area NDA surrounding the display area DA is illustrated as an exemplary, the non-display area NDA may be disposed on one side of the display area DA, or may be omitted in other embodiments.

As illustrated in FIG. 2, the display device DD includes a display module DM, a frame FRM, a bracket BRK, a plurality of male screws OTH1 and OTH2, a first cover BC1, and a second cover BC2.

As shown in FIG. 1, the display module DM may generate images IM1 and IM2. The display module DM includes a flat display area FA (or a flat portion) on which a main image is displayed at a front surface thereof, and also includes a side display area SA (or a side portion) on which a sub image is displayed on a side surface thereof. In the current embodiment, the terms the “flat display area FA” and the “side display area SA” may define the display module DM through a plurality of areas (or portions) that are divided according to their shapes.

In the current embodiment, the display device DD including one side display area SA, which is bent from one side of the flat display area FA, and the display module DM are illustrated as an exemplary. In the current embodiment, a receiver displayed on a background image as the main image IM1 is exemplarily illustrated, and an icon as the sub image IM2 is exemplarily illustrated. The main image IM1 and the sub image IM2 may be combined with each other to provide a single image or information.

The flat display area FA is parallel to a surface/plane that is defined by a first directional axis DR1 and a second directional axis DR2. A normal direction of the flat display area FA is indicated as a third directional axis DR3. The third directional axis DR3 may be a reference axis for distinguishing front and rear surfaces of each of members from each other. The side display area SA that is bent from the flat display area FA (e.g., bent at a 90-degree angle) displays the sub image IM2 in a direction of a fourth directional axis DR4 that crosses the first direction axis DR1, the second directional axis DR2, and the third directional axis DR3 (e.g., between the third directional axis DR3 and the plane defined by the first and second directional axes DR1 and DR2). However, directions that are indicated as the first to fourth directional axes DR1 to DR4 may be a relative concept, and thus may be changed with respect to each other in other embodiments.

Referring to FIGS. 1 and 3, the side display area SA may have a shape that is bent at a curvature radius (e.g., radius of curvature) CR. Here, the curvature radius CR may range from about 2.5 mm to about 3.5. However, the inventive concept is not limited to the above-described range of the curvature radius CR.

When the display device DD is cut by a plane that is defined by the first directional axis DR1 and the third directional axis DR3, the side display area SA may include a curved portion corresponding to a quadrant (e.g., curved to 90 degrees). In this case, a surface area of the side display area SA may increase to further expand an application range of the display device DD. The side display area SA may be bent from the flat display area FA, and the inventive concept is not limited to a shape of the side display area SA.

The display device DD may further include a window member on the display module DM. The window member may define a front surface of the display device DD. The window member may provide an input surface/a touch surface/a display surface for user's input. The window member and the display module DM may be coupled to each other by using an optical transparent adhesion member.

The frame FRM is under the display module DM, and is coupled to the display module DM by a first adhesion member AD1. As shown in FIG. 2, the frame FRM includes a flat surface support portion FST, a side surface support portion SST, and a coupling portion CBN.

The flat surface support portion FST is coupled to correspond to the flat display area FA. An opening OP may be defined in the flat surface support portion FST. A portion of the bracket BRK, or a portion of a component of the display device DD, may correspond to the opening OP.

The side surface support portion SST is coupled to correspond to the side display area SA. The side surface support portion SST and the side display area SA may be coupled or directly coupled to each other using the first adhesion member AD1, or may be indirectly coupled to each other through the flat surface support portion FST and the flat display area FA, which may be coupled to each other by using the first adhesion member AD1.

The frame FRM is coupled to the bracket BRK through the coupling portion CBN. Because the frame FRM is coupled to the display module DM through the first adhesion member AD1, the coupling portion CBN may perform a function for coupling the display module DM to the bracket BRK.

The coupling portion CBN has a structure that is able to be coupled to, and detached from, the bracket BRK. FIG. 2 illustrates a plurality of female screws (e.g., screw holes, or threaded holes) ITH1 and ITH2 as a structure of the coupling portion CBN. That is, the coupling portion CBN may correspond to portions at which the female screws ITH1 and ITH2 are located. The female screws ITH1 and ITH2 may be divided into first female screws ITH1 and second female screws ITH2.

The frame FRM may be formed of a metal, such as stainless steel. However, the inventive concept is not limited to the material of the frame FRM. For example, the frame FRM may be formed of a synthetic resin. The frame FRM may have elasticity due to structural characteristics, a thickness, or properties of a material.

The bracket BRK is under the frame FRM, and is detachable from the frame FRM through the coupling portion CBN. The bracket BRK has a plurality of through holes TH1 and TH2 at an area overlapping the coupling portion CBN.

The plurality of through holes TH1 and TH2 may include first through holes TH1 and second through holes TH2. The first through holes TH1 may be at an area overlapping the first female screws ITH1 with respect to the third directional axis DR3. The second through holes TH2 may be at an area overlapping the second female screws ITH2 with respect to the third directional axis DR3.

A protrusion ETD of the bracket BRK may correspond to the opening OP of the frame FRM. When the protrusion ETD corresponds to the opening OP, the bracket BRK and the frame FRM may be more firmly/securely coupled to each other.

The first cover BC1 is under the bracket BRK to protect the bracket BRK. The bracket BRK may have third through holes TH3 at an area overlapping the second through holes TH2 on the third directional axis DR3. A battery for driving the display device DD may be between the first cover BC1 and the bracket BRK.

As illustrated in FIGS. 2, 3, and 4, the plurality of male screws OTH1 and OTH2 may include first male screws OTH1 and second male screws OTH2. The first male screws OTH1 may be coupled to the corresponding first female screws ITH1 through the corresponding first through holes TH1, respectively. The second male screws OTH2 may be coupled to the corresponding second female screws ITH2 through the corresponding second through holes TH2 and the corresponding third through holes TH3, respectively.

When the first female screws ITH1 and the first male screws OTH1 are coupled to each other, the frame FRM and the bracket BRK may be coupled to each other. When the second female screws ITH2 and the second male screws OTH2 are coupled to each other, the frame FRM, the bracket BRK, and the first cover BC1 may be coupled to each other.

When the female screws ITH1 and ITH2 and the male screws OTH1 and OTH2 are coupled to each other, the male screws OTH1 and OTH2 may be rotated to separate from the female screws ITH1 and ITH2. Thus, the frame FRM, the bracket BRK, and the first cover BC1 may be separated from each other.

As described above, the frame FRM, the bracket BRK, and the first cover BC1 may be assembled with each other so that the frame FRM, the bracket BRK, and the first cover BC1 are detached from each other using the female screws ITH1 and ITH2 and the male screws OTH1 and OTH2.

The second cover BC2 may be under the first cover BC1, and may be coupled to the first cover BC1 through a second adhesion member AD2. The second cover BC2 may protect the first cover BC1, and may prevent the third through holes TH3 of the first cover BC1 from being seen through the rear surface of the display device DD.

If the display module DM including the flat display area FA and the side display area SA is directly coupled to the bracket BRK by using the adhesion member, it may be difficult to detach the display module DM from the bracket BRK later. Also, it may be difficult to firmly couple the display module DM to the bracket BRK through the adhesion member due to the bent shape of the side display area SA. As illustrated in FIGS. 1 to 4, the frame FRM may be relatively easily coupled to the display module DM by using the adhesion member when compared to the bracket BRK. Thus, when the frame FRM is disposed between the display module DM and the bracket BRK, reliability in assembling may be secured. Also, since the frame FRM is easily detached from the bracket BRK, when an error in the display device DD occurs after the display module DM and the bracket BRK are assembled with each other, the display module DM and the bracket BRK may be easily separated from each other to repair the display device DD.

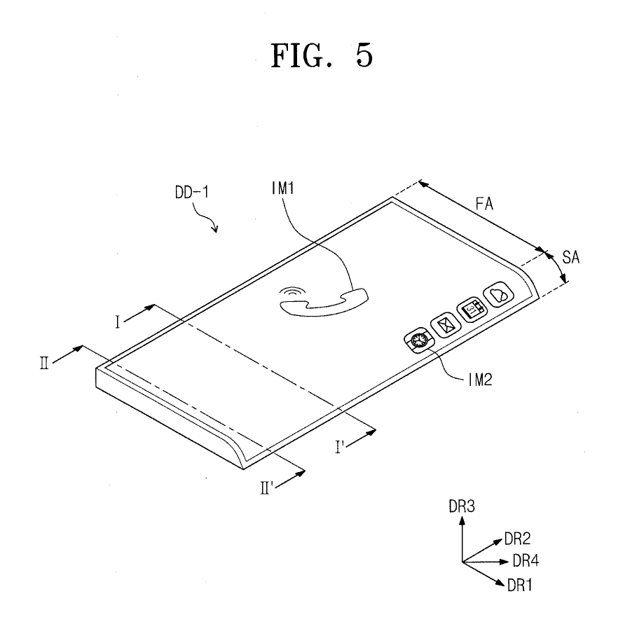

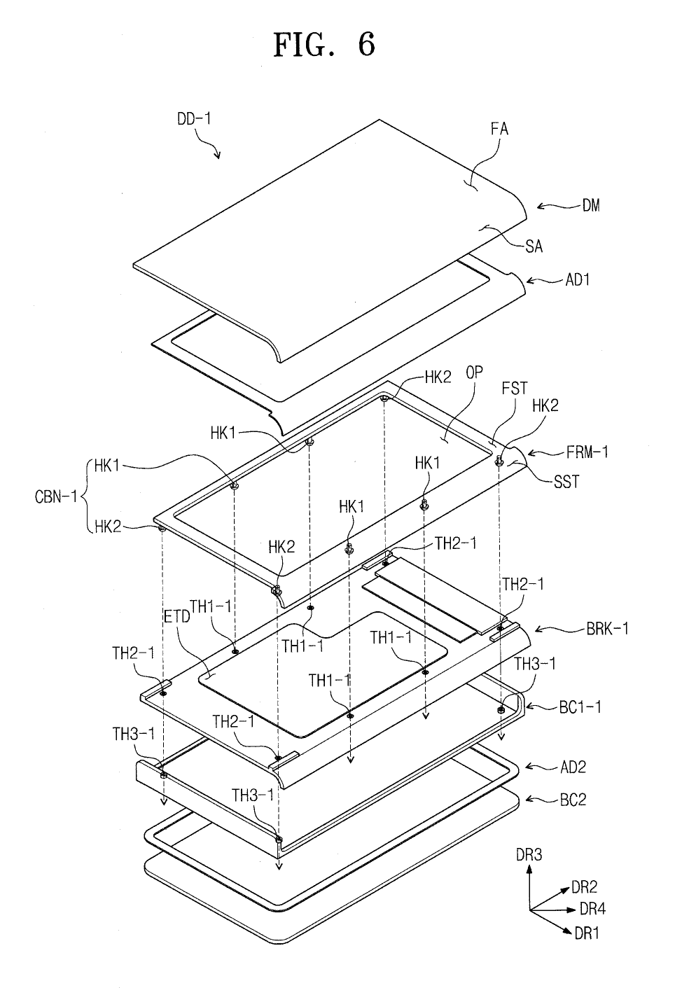

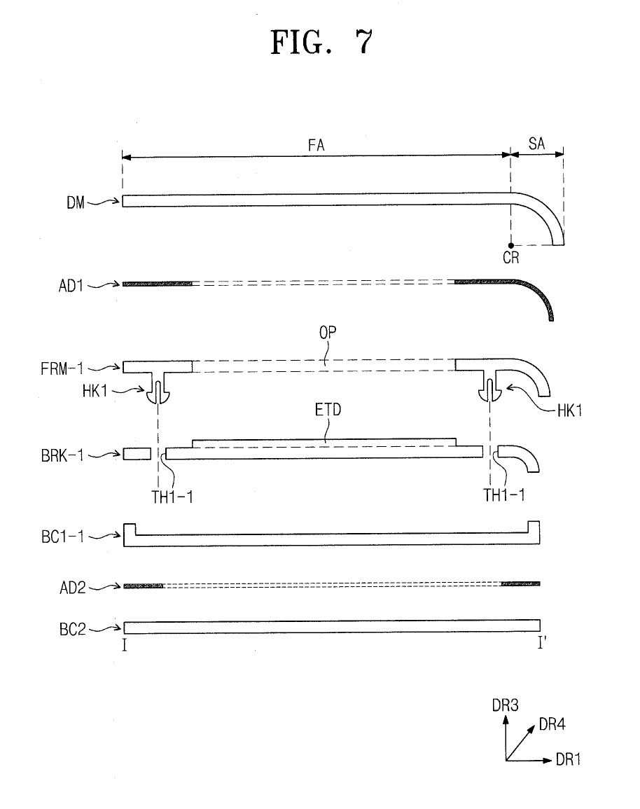

FIG. 5 is a perspective view of a display device DD-1 according to an embodiment of the inventive concept, FIG. 6 is an exploded perspective view of the display device DD-1 of FIG. 5, FIG. 7 is an exploded cross-sectional view of the display device DD-1, taken along the line I-I′ of FIG. 5, and FIG. 8 is an exploded cross-sectional view of the display device DD-1, taken along the line II-II′ of FIG. 5.

As illustrated in FIG. 6, the display device DD-1 includes a display module DM, a frame FRM-1, a bracket BRK-1, a first cover BC1-1, and a second cover BC2.

Because descriptions with respect to the display module DM and the second cover BC are the same as those of FIGS. 1 to 4, their duplicated descriptions will be omitted.

The frame FRM-1 is under the display module DM-1, and is coupled to the display module DM-1 using a first adhesion member AD1. The frame FRM-1 includes a flat surface support portion FST, a side surface support portion SST, and a coupling portion CBN-1.

Because descriptions with respect to the flat surface support portion FST and the side surface support portion SST are the same as those of FIGS. 1 to 4, their duplicated descriptions will be omitted.

The frame FRM-1 is coupled to the bracket BRK-1 through the coupling portion CBN-1. Because the frame FRM-1 is coupled to the display module DM through the first adhesion member AD1, the coupling portion CBN-1 may perform a function for coupling the display module DM to the bracket BRK-1.

The coupling portion CBN-1 has a structure that is able to be coupled to, and detached from, the bracket BRK-1. FIG. 6 illustrates a plurality of hooks/clips HK1 and HK2 as a structure of the coupling portion CBN-1. That is, the coupling portion CBN-1 may correspond to portions at which the hooks HK1 and HK2 are disposed. The hooks HK1 and HK2 may include first hooks HK1 and second hooks HK2.

The frame FRM-1 may be formed of a metal, such as stainless steel. However, the inventive concept is not limited to the material of the frame FRM-1. For example, the frame FRM-1 may be formed of a synthetic resin. The frame FRM-1 may have elasticity due to structural characteristics of, a thickness of, or properties of a material.

The bracket BRK-1 is under the frame FRM-1, and is detachable from the frame FRM-1 through the coupling portion CBN-1. The bracket BRK-1 has a plurality of through holes TH1-1 and TH2-1 at an area overlapping the coupling portion CBN-1.

The plurality of through holes TH1-1 and TH2-1 may include first through holes TH1-1 and second through holes TH2-1. The first through holes TH1-1 may be at an area overlapping the first hooks HK1 with respect to the third directional axis DR3. The second through holes TH2-1 may be at an area overlapping the second hooks HK2 on the third directional axis DR3.

Because descriptions with respect to a protrusion ETD and an opening OP of the bracket BRK-1 are the same as those of FIGS. 1 to 4, their duplicated descriptions will be omitted.

The first cover BC1-1 may be under the bracket BRK-1 to protect the bracket BRK-1. The bracket BRK-1 may have third through holes TH3-1 at an area overlapping the second through holes TH2-1 with respect to the third directional axis DR3. A battery for driving the display device DD-1 may be between the first cover BC1-1 and the bracket BRK-1.

As illustrated in FIGS. 6, 7, and 8, the first hooks HK1 may be inserted into the corresponding first through holes TH1-1, respectively. The second hooks HK2 may be inserted into the corresponding second through holes TH2-1 and into the corresponding third through holes TH3-1.

When the first hooks HK1 are inserted into the first through holes TH1-1, the frame FRM-1 and the bracket BRK-1 may be coupled to each other. When the second hooks HK2 are inserted into the second and third through holes TH2-1 and TH3-1, the frame FRM-1, the bracket BRK-1, and the first cover BC1-1 may be coupled to each other.

When the hooks HK1 and HK2 are respectively inserted into the through holes TH1-1, TH2-1, and TH3-1, the hooks HK1 and HK2 may be adjusted to separate the hooks HK1 an HK2 from the through holes TH1-1, TH2-1, and/or TH3-1. Thus, the frame FRM-1, the bracket BRK-1, and the first cover BC1-1 may be separated from each other.

As described above, the frame FRM-1, the bracket BRK-1, and the first cover BC1-1 may be assembled with each other so that the frame FRM-1, the bracket BRK-1, and the first cover BC1-1 may be detached from each other by using the hooks HK1 and HK2 and the through holes TH1-1, TH2-1, and TH3-1.

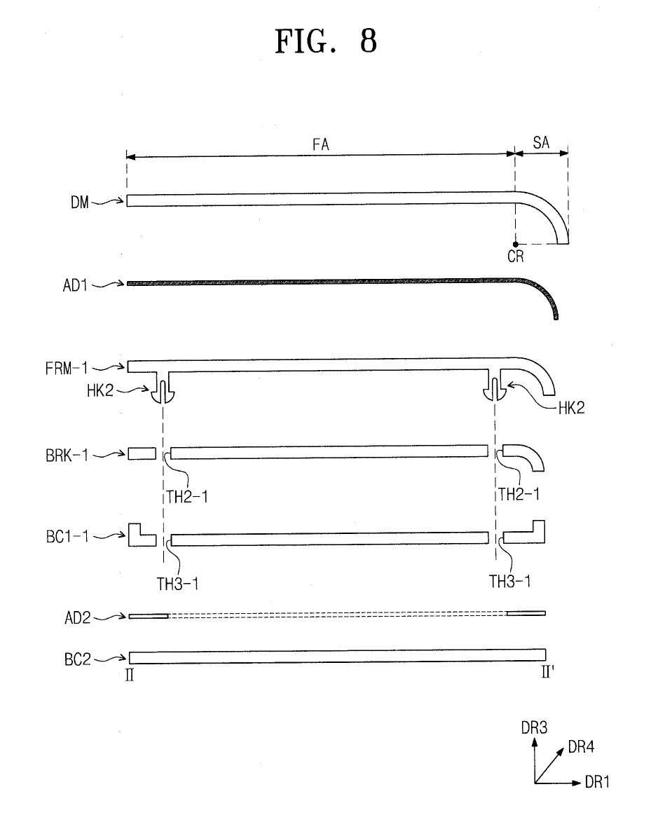

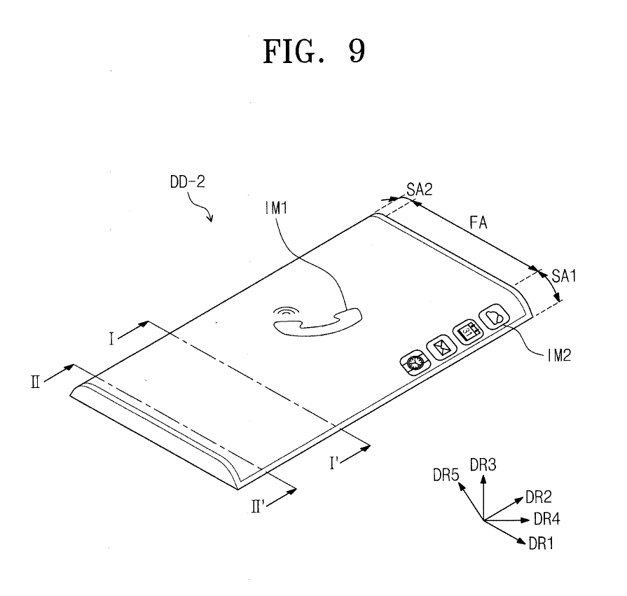

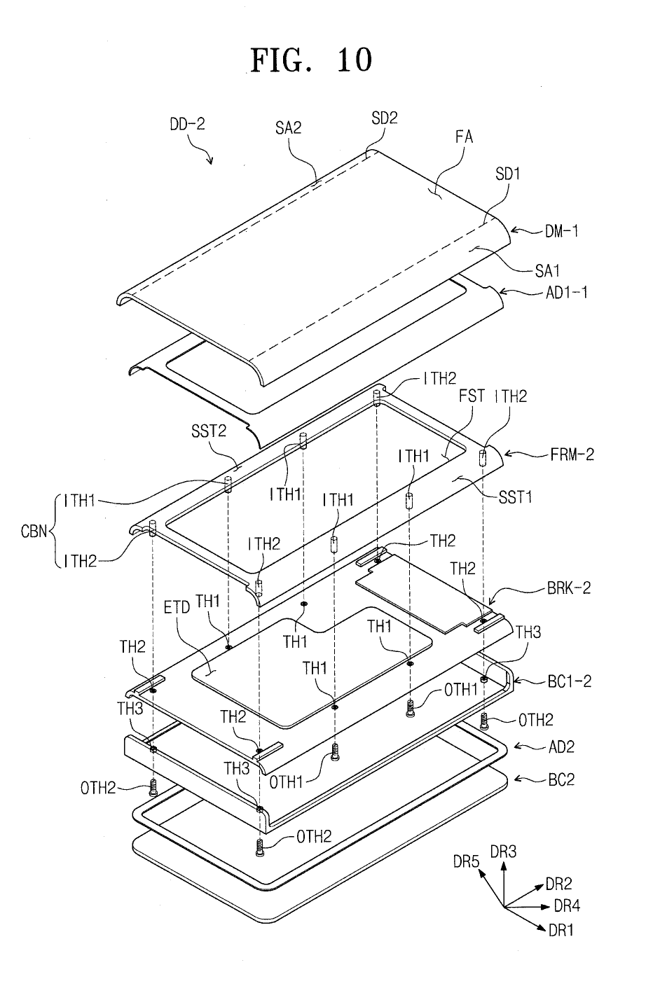

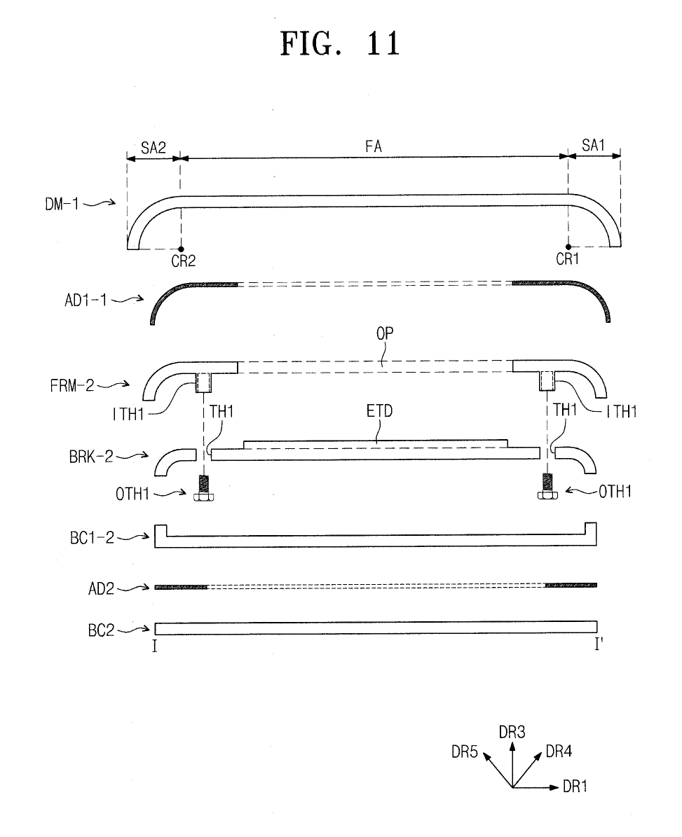

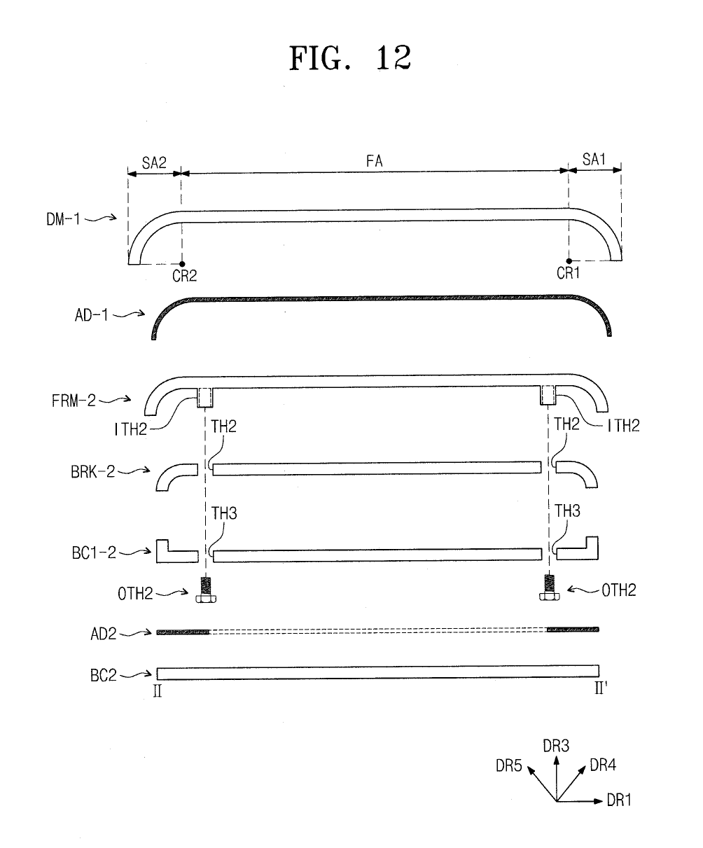

FIG. 9 is a perspective view of a display device DD-2 according to an embodiment of the inventive concept, FIG. 10 is an exploded perspective view of the display device DD-2 of FIG. 9, FIG. 11 is an exploded cross-sectional view of the display device DD-2, taken along the line I-I′ of FIG. 9, and FIG. 12 is an exploded cross-sectional view of the display device DD-2, taken along the line II-II′ of FIG. 9.

As illustrated in FIGS. 9 and 10, the display device DD-2 includes a display module DM-1, a frame FRM-2, a bracket BRK-2, a plurality of male screws OTH1 and OTH2, a first cover BC1-2, and a second cover BC2.

The display module DM-1 generates images IM1 and IM2. The display module DM include a flat display area FA (or a flat portion) on which a main image IM1 is displayed on a front surface thereof, first and second side display areas SA1 and SA2 (or side portions) on which sub images IM2 are respectively displayed. In the current embodiment, the terms “flat display area FA” and “first and second side display areas SA1 and SA2” may define the display module DM through a plurality of areas (or portions) that are categorized according to their shapes.

The first and second side display areas SA1 and SA2 may face each other along the first directional axis DR1. In the current embodiment, a receiver displayed as the main image IM1 is exemplarily illustrated, and an icon as the sub image IM2 is exemplarily illustrated. The main image IM1 and the sub image IM2 may be combined with each other to provide a unitary image or information. The display device DD-2 according to an embodiment may be divided into a display area on which images are displayed, and a non-display area on which images are not displayed (e.g., refer to FIG. 1).

The flat display area FA is parallel to a surface/plane that is defined by the first directional axis DR1 and the second directional axis DR2. A normal direction of the flat display area FA is indicated as the third directional axis DR3. The third directional axis DR3 may be a reference axis for distinguishing front and rear surfaces of each of members from each other.

The first side display area SA1 is bent from a first side SD1 of the flat display area FA. The first side display area SA1 displays the sub image IM2 along the fourth directional axis DR4.

The second side display area SA2 is bent from a second side SD2 of the flat display area FA (e.g., bent at a 90-degree angle). The second side display area SA2 displays an image along a fifth directional axis DR5, which may be an axis that is between the third directional axis DR3 and a plane defined by the first and second directional axes DR1 and DR2. The fourth directional axis DR4 and the fifth directional axis DR5 may be symmetrical to each other with respect to the third directional axis DR3.

Referring to FIGS. 9 and 11, the first side display area SA1 may have a shape that is bent at a first curvature radius CR1. Here, the first curvature radius CR1 may be in a range of about 2.5 mm to about 3.5 mm. The second side display area SA2 may have a shape that is bent at a second curvature radius CR2. Here, the second curvature radius CR2 may be in a range of about 2.5 mm to about 3.5 mm. Here, the first curvature radius CR1 may be the same as the second curvature radius CR2. However, the inventive concept is not limited to the ranges of the first and second curvature radiuses CR1 and CR2.

When the display device DD-2 is cut by a plane that is defined by the first directional axis DR1 and the third directional axis DR3, each of the first and second side display areas SA1 and SA2 may include a curved portion corresponding to a quadrant. In this case, a surface area of each of the first and second side display areas SA1 and SA2 may increase to further expand an application range of the display device DD-2. Each of the first and second side display areas SA1 and SA2 may be bent from the flat display area FA, and also, the inventive concept is not limited to the illustrated shapes of the first and second side display area SA1 and SA2.

The display device DD-2 may further include a window member on the display module DM-1. The window member defines a front surface of the display device DD-2. The window member may provide an input surface/a touch surface/a display surface for user's input. The window member and the display module DM-2 may be coupled to each other by using an optical transparent adhesion member.

The frame FRM-2 is under the display module DM-1, and is coupled to the display module DM-1 by using a first adhesion member AD1-1. The frame FRM-2 includes a flat surface support portion FST, a first side surface support portion SST1, a second side surface support portion SST2, and a coupling portion CBN.

Because descriptions with respect to the flat surface support portion FST and the coupling portion CBN are the same as those of FIGS. 1 to 4, their duplicated descriptions will be omitted.

The first side surface support portion SST1 is coupled to correspond to the first side display area SA1. The second side surface support portion SST2 is coupled to correspond to the second side display area SA2. The first and second side surface support portions SST1 and SST2, and the first and second side display areas SA1 and SA2, may be respectively directly coupled to each other by using the first adhesion member AD1-1, or may be respectively indirectly coupled to each other through the flat surface support portion FST and the flat display area FA, which are coupled to each other by using the first adhesion member AD1-1.

The bracket BRK-2 is under the frame FRM-2 and is detachable from the frame FRM-2 through the coupling portion CBN. The bracket BRK-2 has a plurality of through holes TH1 and TH2 defined in an area(s) overlapping the coupling portion CBN. Because descriptions with respect to the through holes TH1 and TH2 and a protrusion ETD of the bracket BRK-2 are the same as those of FIGS. 1 to 4, their duplicated descriptions will be omitted.

The first cover BC1-2 may be under the bracket BRK-2 to protect the bracket BRK-2. Because descriptions with respect to the third through holes TH3 of the first cover BC1-2 are the same as those of FIGS. 1 to 4, their duplicated descriptions will be omitted. A battery for driving the display device DD-2 may be between the first cover BC1-2 and the bracket BRK-2.

Because descriptions with respect to the plurality of male screws OTH1 and OTH2 are the same as those of FIGS. 1 to 4, their duplicated descriptions will be omitted.

The second cover BC2 may be under the first cover BC1-2, and may be coupled to the first cover BC1-2 through a second adhesion member AD2-1. The second cover BC2 may protect the first cover BC1-2, and may prevent the third through holes TH3 of the first cover BC1-2 from being seen through the rear surface of the display device DD-2.

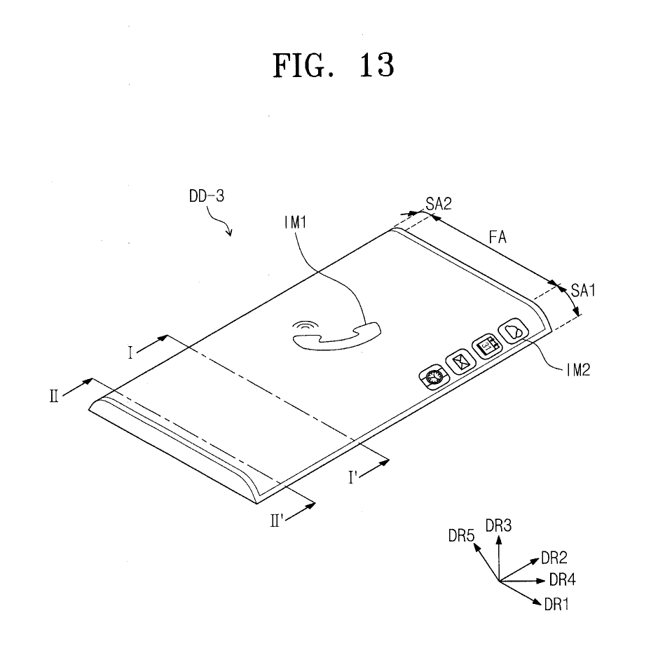

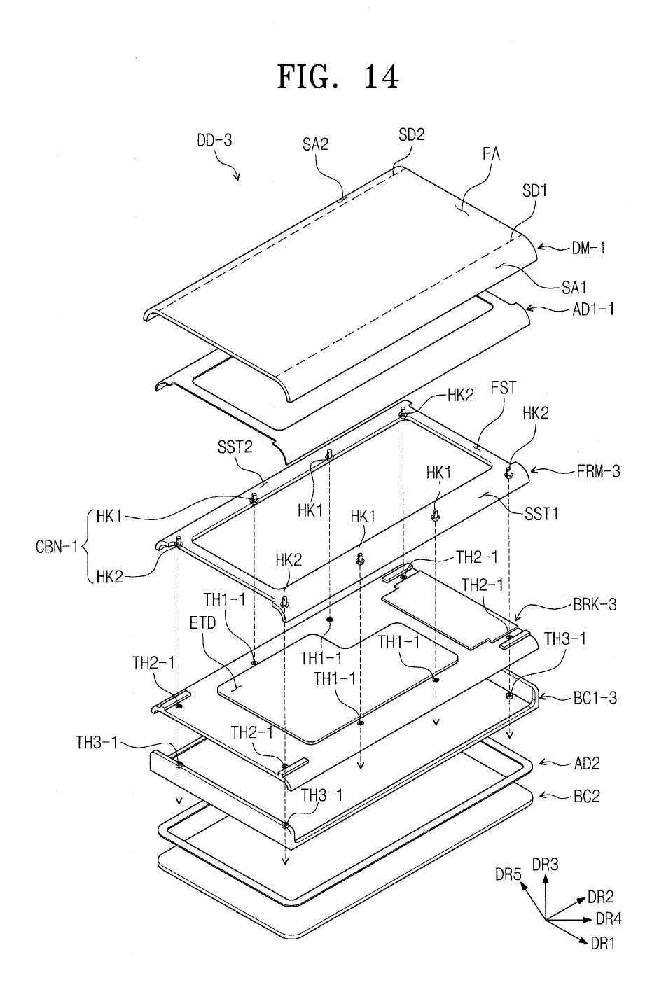

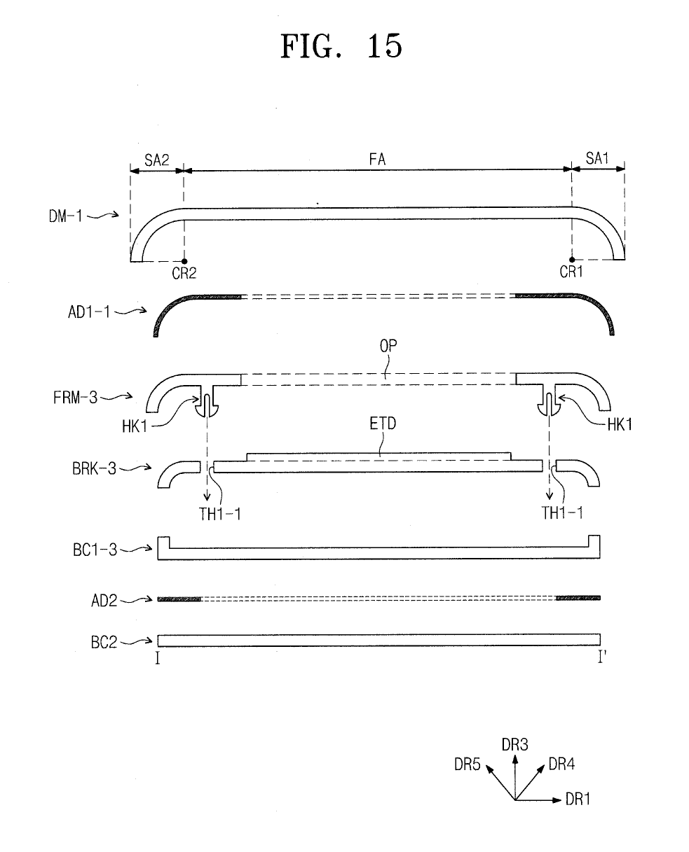

FIG. 13 is a perspective view of a display device DD-3 according to an embodiment of the inventive concept, FIG. 14 is an exploded perspective view of the display device DD-3 of FIG. 13, FIG. 15 is an exploded cross-sectional view of the display device DD-3, taken along the line I-I′ of FIG. 13, and FIG. 16 is an exploded cross-sectional view of the display device DD-3, taken along the line II-II′ of FIG. 13.

As illustrated in FIGS. 13 and 14, the display device DD-3 includes a display module DM-1, a frame FRM-3, a bracket BRK-3, a first cover BC1-3, and a second cover BC2.

Because descriptions with respect to the display module DM-1 and the second cover BC2 are the same as those of FIGS. 9 to 12, their duplicated descriptions will be omitted.

The frame FRM-3 is under the display module DM-1, and is coupled to the display module DM-1 by using a first adhesion member AD1-1. The frame FRM-1 includes a flat surface support portion FST, a first side surface support portion SST1, a side surface support portion SST2, and a coupling portion CBN-1.

Because descriptions with respect to the flat surface support portion FST, the first side surface support portion SST1, and the second side surface support portion SST2 are the same as those of FIGS. 9 to 12, their duplicated descriptions will be omitted. Because descriptions with respect to the coupling portion CBN-1 are the same as those of FIGS. 5 to 8, duplicated descriptions will be omitted.

The frame FRM-3 may be formed of a metal, such as stainless steel. However, an embodiment of the inventive concept is not limited to the material of the frame FRM-3. For example, the frame FRM-3 may be formed of a synthetic resin. The frame FRM-3 may have elasticity due to structural characteristics of, a thickness of, or properties of a material.

The bracket BRK-3 is under the frame FRM-3, and is detachable from the frame FRM-3 through the coupling portion CBN-1. The bracket BRK-1 has a plurality of through holes TH1-1 and TH2-1. Because descriptions with respect to the plurality of through holes TH1-1 and TH2-1 are the same as those of FIGS. 5 to 8, their duplicated descriptions will be omitted.

The first cover BC1-3 may be under the bracket BRK-3 to protect the bracket BRK-3, and may include third through holes TH3-1. Because descriptions with respect to the third through holes TH3-1 of the first cover BC1-3 are the same as those of FIGS. 5 to 8, their duplicated descriptions will be omitted. A battery for driving the display device DD-3 may be between the first cover BC1-3 and the bracket BRK-3.

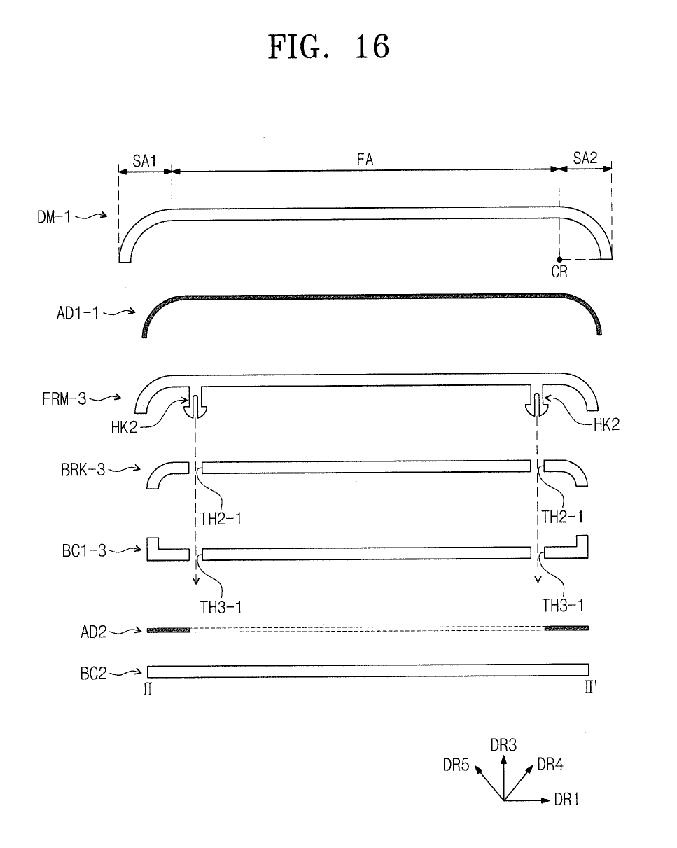

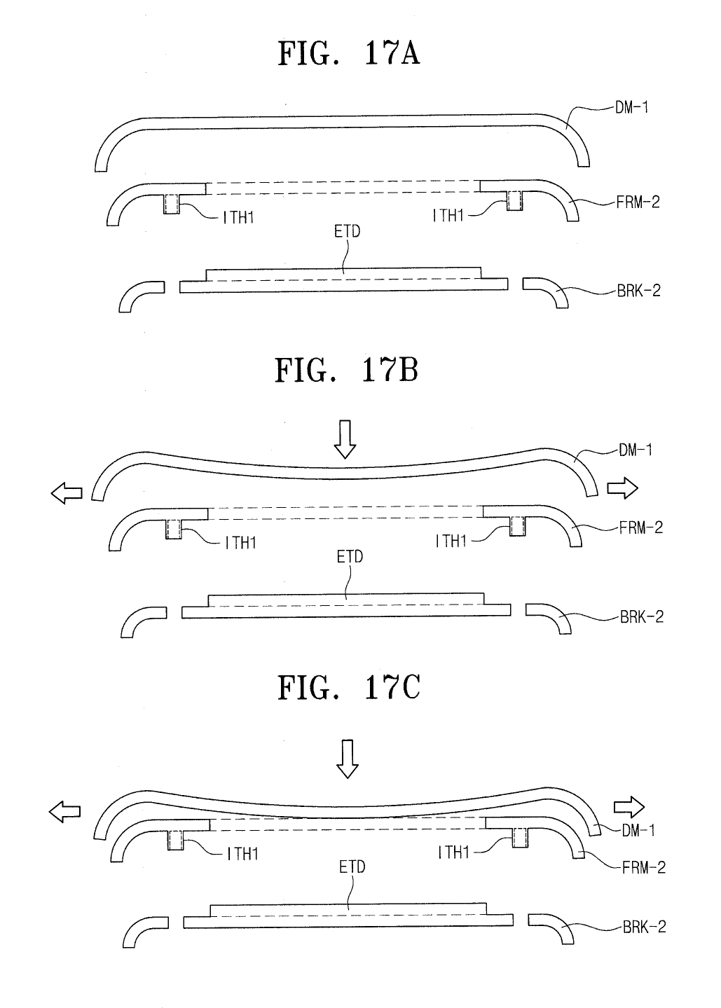

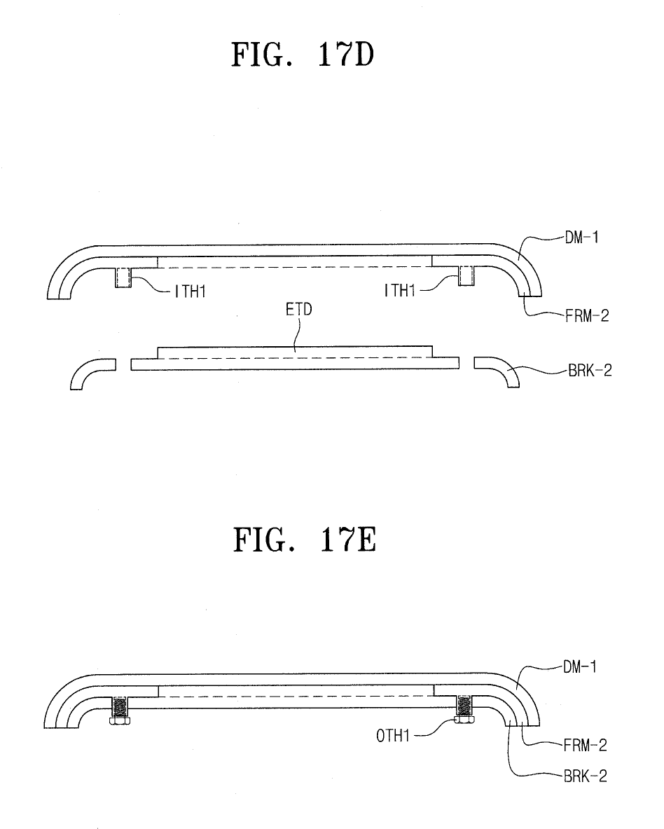

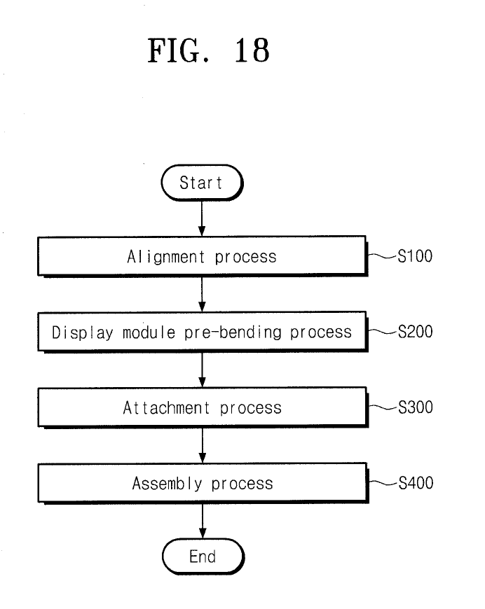

FIGS. 17A, 17B, 17C, 17D, and 17E are cross-sectional views illustrating a method for fabricating the display device DD-2 according to an embodiment of the inventive concept, and FIG. 18 is a flowchart of the method for fabricating the display device DD-2 of FIGS. 17A, 17B, 17C, 17D, and 17E.

FIGS. 17A, 17B, 17C, 17D, 17E, and 18 illustrate a portion of the process of fabricating the display device DD-2 of FIGS. 9 to 12. The method of fabricating the display device DD-2 includes an alignment process S100, a display module pre-bending process S200, an attachment process S300 including a flat surface attachment process and a side surface attachment process, and an assembly process S400.

FIG. 17A illustrates an example of the alignment process S100. A display module DM-1, a frame FRM-2, and a bracket BRK-2 are arranged. Since descriptions with respect to the display module DM-1, the frame FRM-2, and the bracket BRK-2 are the same as those of FIGS. 9 to 12, their duplicated descriptions will be omitted.

Although the display module DM-1, the frame FRM-2, and the bracket BRK-2 are arranged in a line, or are aligned, in FIG. 17A, the inventive concept is not limited thereto. The fabrication process may be performed by arranging only the display module DM-1 and the frame FRM-2 in a line, and then the bracket BRK-2 may be additionally arranged.

FIG. 17B illustrates an example of the pre-bending process S200. Because the display module DM-1 has a flexible property that is bendable, force may be applied to an upper, left, or right side of the display module DM-1 to allow the display module DM-1 to be bent (e.g., bent at a predetermined curvature).

FIG. 17C illustrates an example of the flat surface attachment process as part of the attachment process S300. In the flat surface attachment process portion of the attachment process S300, a flat display area FA of the display module DM-1, and a flat surface support portion FST of the frame FRM-2, are attached to each other. An adhesion member may be between the flat display area FA and the flat surface support portion FST.

FIG. 17D illustrates an example of the side surface attachment process as part of the attachment process S300. In the display module pre-bending process S200, the force applied to the display module DM-1 may be removed, or force opposite to the force applied to the display module DM-1 in the display module pre-bending process S200 may be applied to allow the display module DM-1, which may be bent at the predetermined curvature, to return its original shape.

While the display module DM-1 returns to its original shape, the first side display area SA1 and the first side surface support portion SST1 are attached to each other, and the second side display area SA2 and the second side surface support portion SST2 are attached to each other. An adhesion member may be between the first side display area SA1 and the first side surface support portion SST1, and the same or a different adhesion member may be between the second side display area SA2 and the second side surface support portion SST2.

FIG. 17E illustrates an example of the assembly process S400. In the assembly process S400, the frame FRM-2 may be detachably coupled to the bracket BRK-2. While the frame FRM-2 and the bracket BRK-2 are assembled with each other, first female screws ITH1 and first male screws OTH1 are used. Because descriptions with respect to the first female screws ITH1 and the first male screws OTH1 are the same as those of FIGS. 1 to 4, their duplicated descriptions will be omitted.

The assembly process S400 may further include a process of assembling a first cover BC1-2 (see FIG. 10) and a second cover BC2 (see FIG. 10) with each other.

Although the method of fabricating the display device DD-2 of FIGS. 9 to 12 is illustrated in FIGS. 17A to 17E, the inventive concept is not limited thereto. As illustrated in FIGS. 13 to 16, the display module DM-1 may be coupled to the bracket BRK-3 by using hooks HK1 and HK2 of the frame FRM-3.

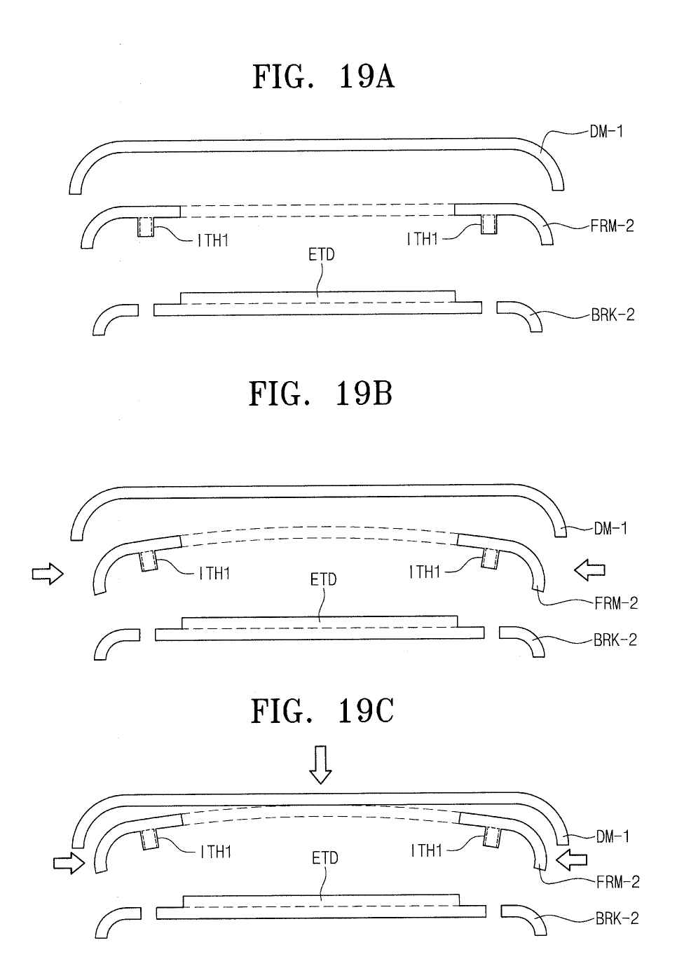

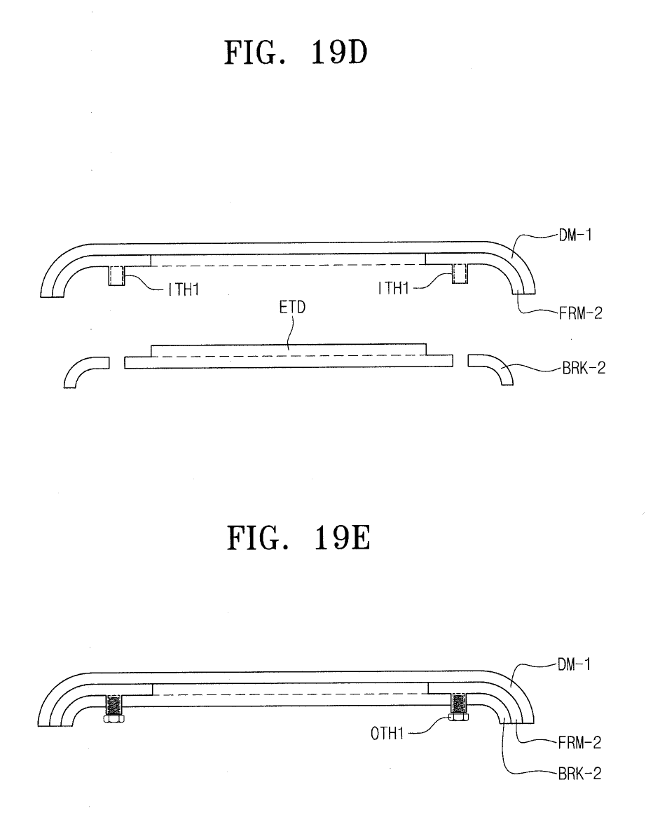

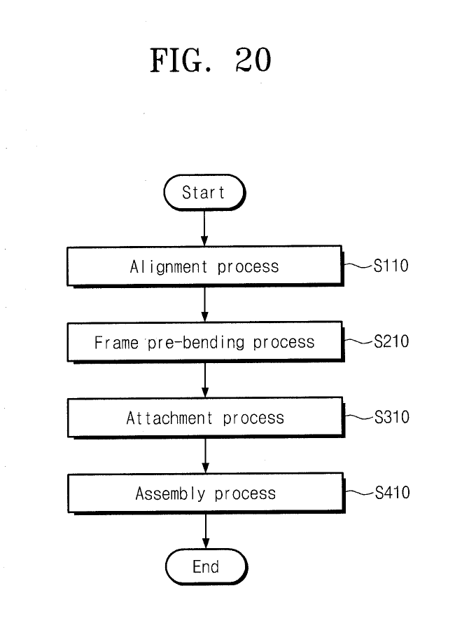

FIGS. 19A, 19B, 19C, 19D, and 19E are cross-sectional views illustrating a method for fabricating the display device DD-2 according to an embodiment of the inventive concept, and FIG. 20 is a flowchart of the method for fabricating the display device DD-2 of FIGS. 19A to 19E.

FIG. 19A illustrates an example of the alignment process S110. Because descriptions with respect to the alignment process S110 are the same as those of the alignment process S100 of FIGS. 17A and 18, its duplicated descriptions will be omitted.

FIG. 19B illustrates an example of a frame pre-bending process S210. Because the frame FRM-2 has a flexible property that is bendable, force may be applied to a lower or left/right side of the frame FRM-2 to allow the frame FRM-2 to be bent (e.g., bent at a predetermined curvature).

FIG. 19C illustrates an example of a flat surface attachment process as part of the attachment process S310. In the flat surface attachment process, a flat display area FA of the display module DM-1, and a flat surface support portion FST of the frame FRM-2, are attached to each other. An adhesion member may be between the flat display area FA and the flat surface support portion FST.

FIG. 19D illustrates an example of a side surface attachment process as part of the attachment process S310. In the frame pre-bending process S210, the force applied to the frame FRM-2 may be removed, or force opposite to the force applied to the frame FRM-2 in the frame pre-bending process S210 may be applied to allow the frame FRM-2, which may be bent at the predetermined curvature, to return its original shape.

While the frame FRM-2 returns to its original shape, the first side display area SA1 and the first side surface support portion SST1 are attached to each other, and the second side display area SA2 and the second side surface support portion SST2 are attached to each other. An adhesion member may be between the first side display area SA1 and the first side surface support portion SST1, and an adhesion member may be between the second side display area SA2 and the second side surface support portion SST2.

FIG. 19E illustrates an example of the assembly process S410. Because descriptions with respect to the assembly process S410 are the same as those of the assembly process S400 of FIGS. 17E and 18, duplicated descriptions will be omitted.

Although the method of fabricating the display device DD-2 of FIGS. 9 to 12 is illustrated in FIGS. 19A to 19E, the inventive concept is not limited thereto. As illustrated in FIGS. 13 to 16, the display module DM-1 may be coupled to the bracket BRK-3 by using hooks HK1 and HK2 of the frame FRM-3.

As described above, the display module and the bracket may be detached through the frame that is attached to the display module. Thus, if product defects occur after the display module and the bracket are assembled, the display module and the bracket may be separated.

According to the above-described fabricating method, the display module, in which a portion of the display area is bent, and the frame may be attached to each other.

It will be apparent to those skilled in the art that various modifications and variations can be made in the present invention. Thus, it is intended that the present invention covers the modifications and variations of this invention provided they come within the scope of the appended claims and their equivalents.

Hence, the real protective scope of the inventive concept shall be determined by the technical scope of the accompanying claims and their equivalents.

What is claimed is:

1. A display device comprising:
a display module comprising:
a flat display area; and
a first side display area that is bent from a first side of the flat display area;
a frame under the display module, and comprising:
a flat surface support portion that is overlapped with the flat display area,
a first side surface support portion that is overlapped with the first side display area; and
a coupling portion; and
a bracket under the frame, and being detachably coupled to the frame through the coupling portion.

2. The display device of claim 1, wherein the flat surface support portion defines an opening.

3. The display device of claim 2, wherein the frame comprises stainless steel.

4. The display device of claim 1, wherein the first side display area of the display module comprises a curved portion corresponding to a quadrant on a cross section that is orthogonal to the first side.

5. The display device of claim 1, further comprising an adhesion member configured to couple the display module to the frame.

6. The display device of claim 5, wherein the coupling portion of the frame comprises a plurality of first female screws,
wherein the bracket defines a plurality of first through holes at an area overlapping the plurality of first female screws, and
wherein the display device further comprises a plurality of first male screws configured to be coupled to the plurality of first female screws through the plurality of first through holes.

7. The display device of claim 6, further comprising a cover under the bracket.

8. The display device of claim 7, wherein the coupling portion of the frame further comprises a plurality of second female screws,
wherein the bracket further defines a plurality of second through holes at an area overlapping the plurality of second female screws,
wherein the cover defines a plurality of third through holes at an area overlapping the plurality of second through holes, and
wherein the display device further comprises a plurality of second male screws configured to be coupled to the plurality of second female screws through the plurality of second and third through holes.

9. The display device of claim 5, wherein the coupling portion of the frame comprises a plurality of first hooks, and
wherein the bracket defines a plurality of first through holes for receiving the plurality of first hooks.

10. The display device of claim 9, further comprising a cover under the bracket.

11. The display device of claim 10, wherein the coupling portion of the frame comprises a plurality of second hooks,
wherein the bracket further comprises a plurality of second through holes for receiving the plurality of second hooks, and
wherein the cover comprises third through holes for receiving the second hooks.

12. The display device of claim 1, wherein the display module further comprises a second side display area that is bent from a second side of the flat display area that is opposite the first side of the flat display area.

13. The display device of claim 12, wherein the frame further comprises a second side surface support portion overlapping the second side display area.

14. The display device of claim 13, wherein the first side display area and the second side display area have the same radius of curvature, and
wherein the first side surface support portion and the second side surface support portions have the same radius of curvature.

15. A method for fabricating a display device, the method comprising:
performing an alignment process in which a display module, which comprises a flat display area, a first side display area bent from a first side of the flat display area, and a second side display area bent from a second side of the flat display area that is opposite the first side, is aligned with a frame, which comprises a flat surface support portion, a first side surface support portion, a second side surface support portion, and a coupling portion, and is also aligned with a bracket;
performing a pre-bending process in which at least one of the flat display area and the flat surface support portion is bent;
performing an attachment process in which:
the flat display area and the flat surface support portion are attached to each other;
the first side display area and the first side surface support portion are attached to each other; and
the second side display area and the second side surface support portion are attached to each other; and
performing an assembly process in which the frame is coupled to the bracket by using the coupling portion so that the frame is detachable from the bracket.

16. The method of claim 15, wherein the display module comprises a curved portion corresponding to a quadrant on a cross-section that is orthogonal to the first side.

17. The method of claim 15, wherein the coupling portion of the frame defines a plurality of female screws,
wherein the bracket defines a plurality of through holes, and
wherein a plurality of male screws are coupled to the plurality of female screws through the plurality of through holes during the assembly process.

18. The method of claim 15, wherein the coupling portion of the frame comprises a plurality of hooks, and
wherein the bracket defines a plurality of through holes into which the plurality of hooks are inserted during the assembly process.

19. The method of claim 15, wherein the at least one of the flat display area and the flat surface support portion that is bent returns to its original shape during the performing the attachment process.
